(19) United States
(12) Patent Application Publication
(10) Pub. No.: US 2007/0290303 A1
(43) Pub. Date: Dec. 20, 2007

(54) DUAL LEADFRAME SEMICONDUCTOR DEVICE PACKAGE

(75) Inventor: Bernhard P. Lange, Freising (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 11/758,569

(22) Filed: Jun. 5, 2007

Related U.S. Application Data
(60) Provisional application No. 60/882,399, filed on Dec. 28, 2006.

(30) Foreign Application Priority Data
Jun. 7, 2006 (DE) 10 2006 026 471.1

(51) Int. Cl. H01L 23/495

(52) U.S. Cl. 257/669; 257/E23.042; 257/E23.045; 257/E23.051

(57) ABSTRACT

A semiconductor device (10) comprises a die (11) provided between a first leadframe (12) and a second leadframe (13), such that a first surface of the die (11) is connected to the first leadframe (12) and a second surface of the die (11) is connected to a second leadframe (13). Mold compound (15) includes side recesses (16) into which end portions (18) of leadframe (12) can be fit.

The invention generally relates to a semiconductor device. More particularly, but not exclusively, the invention relates to a package design for a leadless semiconductor device package.

### BACKGROUND

Leadless semiconductor device packages are very widely used in the semiconductor industry and have numerous applications, due to the fact that the package outline is very small. Current designs for such device packages employ a semiconductor device (die) connected to a single leadframe, which is mounted on a substrate. In these designs it is possible to achieve a low inductance but the transient power dissipation is limited because the thickness of the die pad supporting the die in the central portion of the leadframe needs to be equivalent to the lead thickness. Furthermore, larger device packages have a larger thermal expansion difference between the package and the circuit board upon which the end user mounts the package. This can result in solder joint failures when the application is thermally cycled, for example by power on/off cycles.

The invention has been devised with the foregoing in mind.

### SUMMARY

Thus, the invention provides a semiconductor device, comprising a die provided between a first leadframe and a second leadframe such that the first leadframe is connected to a first surface of the die and the second leadframe is connected to a second surface of the die. Preferably the first leadframe is connected to the active (chip active) side of the die and the second leadframe is connected to the inactive side of the die, which does not take part in conduction. The first leadframe should ideally generally oppose the second leadframe in a direction of the device thickness (perpendicular to a plane containing the first and second surfaces of the die).

Having two leadframes in the device, provided on either side of the die, allows for one leadframe to be thicker than the other and act as a heat sink. This means that a higher power dissipation is possible in the device package.

Preferably, the first leadframe comprises pin portions overlaying a part of the first surface. One end of each of the pin portions can then be attached to the active surface of the die. The second leadframe should ideally comprise a pad portion upon which the second surface of the die can rest. In this way, the second leadframe is a die pad, which can support the die and act as a heat sink for conducting heat away from the die. However, the second leadframe can also include pin portions provided on the periphery of the die pad. Ideally the semiconductor device should be arranged so that the second leadframe is placed on a substrate, with the die placed on top of the die pad portion of the second leadframe. When the die is placed on top of the second leadframe, it should be arranged so that the first chip active surface is facing upwards for connection to the pin portions of the first leadframe.

The first surface and the second surface can be connected to the first and second leadframes by any suitable means, for example solder bonds or bond wire. The second surface should ideally be attached to the second leadframe by a die attach material such as film, epoxy resin or solder.

The device may further comprise a mold compound configured to encapsulate the die and the first and second leadframes, apart from at the ends of the pin portions on the first leadframe not connected to the active surface of the die, and on the lower surface of the second leadframe (the side of the second leadframe not connected to the die). A part of the pin portions of the first leadframe can then extend outside the mold compound. The outside surface of the mold compound can be provided with a recess for receiving the part of each pin portion of the leadframe that extends outside the mold compound. It is then possible to bend this portion of the leadframe downwards towards the substrate so that it extends in a direction perpendicular to the direction of extension of the first leadframe encapsulated by the mold compound. The part of the first leadframe provided outside the mold compound then occupies the recess provided in the outside surface of the mold compound. In this way, the end of the first leadframe not connected to the active surface of the die can be connected to a substrate or circuit board. Furthermore, this means that the parts of the first leadframe provided outside the mold compound are flush with the package sides and the lower surface of the package (that is to be attached to a circuit board). However, the tips of the first leadframe can also extend below the lower surface of the device package.

Providing part of the first leadframe outside the device package means that a lower electrical connection resistivity can be achieved from the chip to the outside of the package. The leadframe can be plated, either before or after the device is assembled, so that the ends form a solderable surface that can be soldered to a circuit board. The leadframe side tip that is to be connected to the circuit board is preferably preplated, for example with NiPdAu to form a solderable surface. However, the leadframe tip can also be postplated after the device is assembled with NiPdAu or any other solderable surface.

The recesses provided on the outside surface of the mold compound may have a volume greater than the part of the pin portion extending outside the mold compound. For example, the recess can be inclined so as to taper inwards from the active surface of the die down towards the substrate. This allows for a clearance angle in the recess, which enables the end of the first leadframe to flex when it thermally expands due to heating during use. Furthermore, both the sides of the first leadframe and the tips of the first leadframe may be soldered to a circuit board. During the soldering process the solder will wet both to the lead tip area and the sides of the leads, allowing a larger solderable surface. This enables an improved connection to the board to be achieved and an end user can easily inspect the solder joint. Thermal expansion differences between the semiconductor package and the circuit board are compensated for by the lead flexibility outside the package.

In the invention, the die pad of the second leadframe can be thicker than the pin portions of the first leadframe, since they are formed as two separate leadframes. This leads to an improved thermal transfer capability for transferring heat from the die through the second leadframe.

### BRIEF DESCRIPTION OF THE DRAWINGS

Further advantages and characteristics of the invention ensue from the description below of the preferred embodiments, and from the accompanying drawings, in which:

FIG. 1 is a cross-sectional side view of a semiconductor device package before completion of the trim and form process according to a first embodiment of the invention;

FIG. 2 is a top view of a leadframe without a die pad for use in a semiconductor device package;

FIG. 3 is a top view of a die pad leadframe for use in a semiconductor device package;

FIG. 4 is a cross-sectional side view of a semiconductor device package after completion of the trim and form process according to a first embodiment of the invention; and

FIG. 5 is a cross-sectional side view of a semiconductor device package after completion of the trim and form process according to a second embodiment of the invention.

### DETAILED DESCRIPTION OF EMBODIMENTS

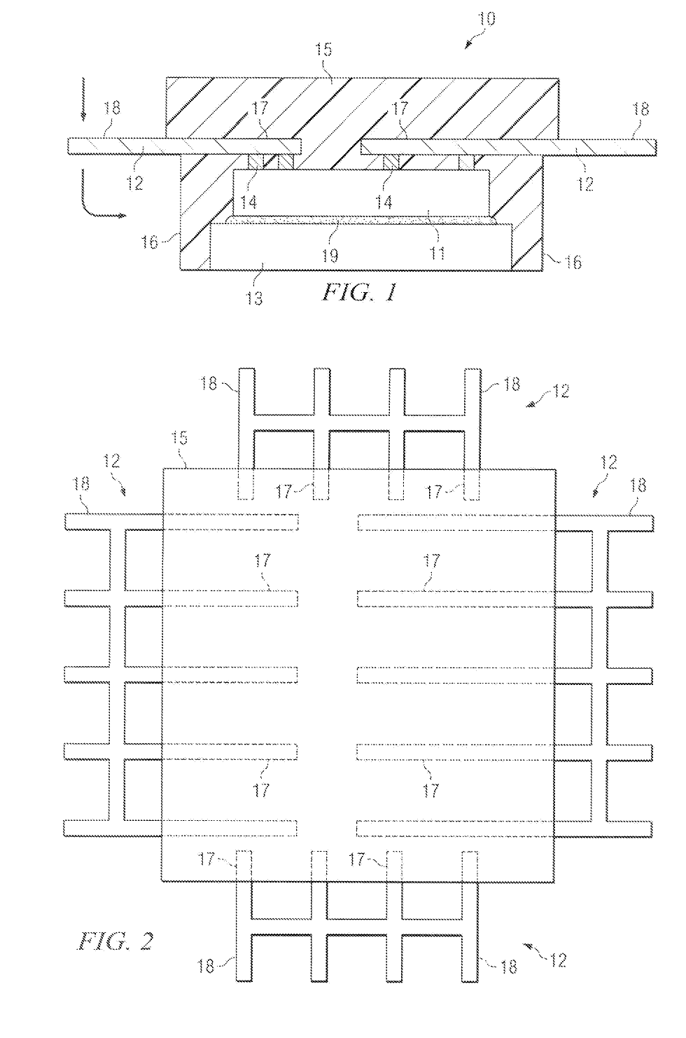

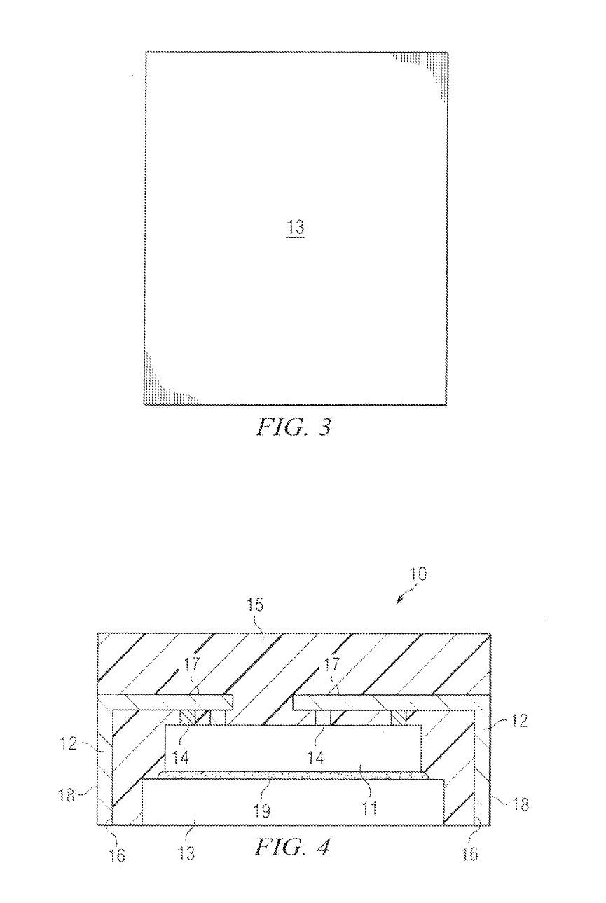

A first embodiment of the invention will now be described with reference to FIGS. 1 to 4. A semiconductor device 10 has a die 11, which is the active semiconductor chip. The die 11 has an active surface connected to a leadframe 12 positioned on top of the die 11 and an inactive surface connected to a die pad 13 provided below the die 11. The leadframe 12 has pin portions 17 and end portions 18. The pin portions 17 of the leadframe 12 establish the connection with the die 11. The leadframe 12 and the die pad 13 are shown from above in FIGS. 2 and 3, respectively. The die pad 13 is actually also a leadframe structure and may additionally comprise pin portions positioned peripherally to the die pad portion.

Connection of the die 11 to the leadframe 12 takes place through connectors 14. The connectors 14 can be metal solder bumps or bonding wires, for example. The connectors 14 may also, for example, be comprised of a combination of solder bumps and bond wire. Connection of the die 11 to the die pad 13 takes place through a die attachment element 19, which can be made of any suitable thermally conducting material, for example film adhesive, epoxy resin or solder. The die 11, top and side portions of die pad 13 and pin portions 17 of the leadframe 12 are encapsulated in a mold compound 15.

FIG. 1 shows the device 10 after it has been molded in the mold compound 15 but before it has been fully formed. The end portions 18 of the leadframe 12 protrude outside the mold compound 15, so that they extend horizontally outwards of the sides of the device 10. The mold compound 15 is formed so that recesses 16 are provided in the sides of the mold compound 15. Each of the recesses 16 have the same size and shape as the end portions 18 so that the end portions 18 of the leadframe 12 can fit into the recesses 16.

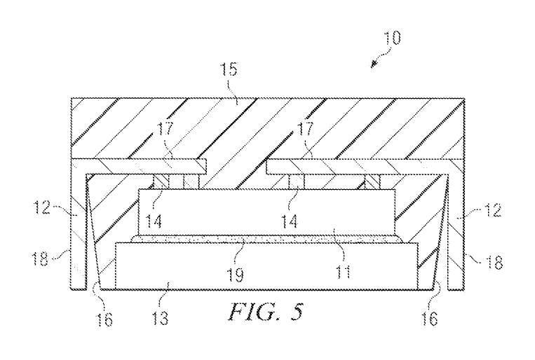

The leadframe 12 is made from a flexible metal so that, when pressure is applied to the top of each of the end portions 18 of the leadframe 12, the end portions 18 are caused to bend downwards and inwards towards the sides of the mold compound 15. The end portions 18 are then received in the recesses 16 such that the tip of each of the end portions 18 is flush with the bottom surface of the die pad 13; i.e., with the bottom surface of the device 10. This is shown in FIG. 4. Alternatively, the end portions 18 can be longer so that they extend below the bottom surface of the device 10.

The tips of each of the end portions 18 are plated with a solderable material, for example NiPdAu, and can then be soldered to a substrate (not shown here) so as to establish a connection between the device 10 and the substrate. When the end portions 18 are received in the recesses 16, they are also flush with the sides of the mold compound 15, so that all surfaces of the device 10 are flat.

During use, electrical connectivity to the die 11 takes place through the pin portions 17 of the leadframe 12 and the die pad 13. The die 11 rests on the die pad 13 and the die pad 13 acts as a heat sink to conduct heat away, via the die attach element 19, from the die 11, which can get hot during use.

FIG. 5 shows a second embodiment of the invention in which the recesses 16 provided in the mold compound 15 are inclined and taper inwards from the leadframe 12 to the lower surface of the die pad 13. When the end portions 18 of the leadframe 12 are bent downwards into the recesses 16, they are thus not completely received in the recesses 16 and there is a gap between the end portions 18 and the sides of the mold compound 15.

Heat dissipated in the leadframe 12 during operation of the device 10 leads to thermal expansion forces in the leadframe 12. These forces cause the end portions 18 of the leadframe 12 to flex. Therefore, the gap provided between the end portions 18 and the sides of the mold compound 15 allows the end portions 18 to flex inwards.

In a traditional leadframe having pin portions provided around the edge of a die pad, it is not possible for the die pad to be thicker than the pin portions. This is because the die would be held above the surface of the pin portions and would therefore not be able to contact the pin portions. However, because the die pad 13 and the top leadframe 12 are formed separately in both embodiments, the die pad 13 can be thicker than the pin portions of the leadframe 12 and the die 11 can still contact the pin portions 17. Because the die pad 13 can be thicker than the leadframe 12, this allows the device 10 to have an improved thermal transfer capability; i.e., more heat can be conducted away from the die 11, leading to improved power dissipation in the device 10.

Although the invention has been described hereinabove with reference to specific embodiments, it is not limited to these embodiments and no doubt further alternatives will occur to the skilled person that lie within the scope of the invention as claimed.

What is claimed is:

1. A semiconductor device, comprising a die provided between a first leadframe and a second leadframe such that the first leadframe is connected to a first surface of the die and the second leadframe is connected to a second surface of the die.

2. A semiconductor device according to claim 1, wherein the first surface of the die is an active surface and the second surface of the die is an inactive surface.

3. A semiconductor device according to claim 1, wherein the first leadframe generally opposes the second leadframe in a direction perpendicular to a plane containing the first surface and the second surface.

4. A semiconductor device according to claim 1, wherein the first leadframe comprises pin portions, one end of each of said pin portions being connected to the first surface.

5. A semiconductor device according to claim 4, wherein an end of each of the pin portions not connected to the first surface of the die is plated with a solderable material.

6. A semiconductor device according to claim 1, wherein the second leadframe comprises a die pad portion.

7. A semiconductor device according to claim 6, wherein the die is provided on the die pad portion such that the second surface rests on the die pad portion.

8. A semiconductor device according to claim 1, wherein the first surface is connected to the first and second leadframes by bond wire.

9. A semiconductor device according to claim 1, wherein the first surface is connected to the first and second leadframes by solder bonds and the second surface is connected to the second leadframe by a die attach material.

10. A semiconductor device according to claim 1, further comprising a mold compound configured to encapsulate the die, and a first portion of the first leadframe and a first portion of the second leadframe.

11. A semiconductor device according to claim 10, wherein a second portion of the first leadframe extends outside the mold compound.

12. A semiconductor device according to claim 11, wherein the second portion of the first leadframe extends in a direction generally perpendicular to a direction of extension of the first portion of the first leadframe.

13. A semiconductor device according to claim 11, wherein the mold compound comprises a recess defined on an outside surface configured to receive the second portion of the first leadframe.

14. A semiconductor device according to claim 13, wherein the volume of the recess is greater than the volume of the second portion of the first leadframe.

15. A semiconductor device according to claim 14, wherein the recess is tapered so as to be wider at an end in which an end of the second portion of the first leadframe distal from the first portion of the first leadframe is received.

16. A semiconductor device according to claim 13, wherein the recess is configured to receive the second portion of the first leadframe such that the second portion of the first leadframe is flush with the outside surface of the mold compound.
